(19) United States
(12) Patent Application Publication
(10) Pub. No.: US 2013/0027896 A1
(43) Pub. Date: Jan. 31, 2013

(54) ELECTRONIC COMPONENT EMBEDDED PRINTED CIRCUIT BOARD AND METHOD OF MANUFACTURING THE SAME

(71) Applicants: Seung Eun LEE, Gyeonggi-do (KR); Hyun Ho Kim, Gyeonggi-do (KR); Yee Na Shin, Seoul (KR)

(72) Inventors: Seung Eun LEE, Gyeonggi-do (KR); Hyun Ho Kim, Gyeonggi-do (KR); Yee Na Shin, Seoul (KR)

(73) Assignee: SAMSUNG Electro-Mechanics Co., Ltd.

(21) Appl. No.: 13/358,247

(22) Filed: Jan. 25, 2012

(30) Foreign Application Priority Data
Jul. 29, 2011 (KR) 10-2011-0076055

(51) Int. Cl. H05K 1/18; H05K 3/30

(52) U.S. Cl. 361/761; 29/832

(57) ABSTRACT

The present invention relates to an electronic component embedded printed circuit board including: a substrate in which a cavity is formed; a plurality of electronic components embedded in the cavity; a metal member inserted between the plurality of electronic components; and insulating layers formed on both surfaces of the substrate to cover the plurality of electronic components, and it is possible to effectively improve heat radiation characteristics.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2011-0076055, entitled filed Jul. 29, 2011, which is hereby incorporated by reference in its entirety into this application.”

### BACKGROUND OF THE INVENTION

1. Field of the Invention

The present invention relates to a printed circuit board, and more particularly, to an electronic component embedded printed circuit board and a method of manufacturing the same.

2. Description of the Related Art

In recent times, due to development of electronics industry, there is a rapidly increasing demand for high performance and miniaturization of electronic components. Accordingly, there is also a demand for high density wiring and thinning of a printed circuit board on which the electronic components are mounted.

A component mounting method different from a conventional component mounting method has been proposed in order to reflect this demand and that is an embedded printed circuit board which seeks high integration and reliability improvement of components or performance improvement of a package itself through organic combination by mounting electronic components such as active devices or passive devices inside a printed circuit board.

The above embedded printed circuit board uses a method in which an opening for inserting an electronic component is formed in a prefabricated core substrate, the electronic component is embedded in the opening, and an insulating material is filled between the electronic component and the core substrate to fix the embedded electronic component.

However, a conventional embedded printed circuit board has a problem that a portion in which an electronic component is embedded or portions connected by wire bonding are damaged due to heat generated when the electronic component is driven. Due to this, there is a problem of deterioration of reliability of the embedded printed circuit board.

Especially, when a plurality of electronic components are embedded in an opening of a core substrate according to high integration of components, this problem becomes serious.

### SUMMARY OF THE INVENTION

The present invention has been invented in order to overcome the above-described problems and it is, therefore, an object of the present invention to provide an electronic component embedded printed circuit board capable of effectively improving heat radiation characteristics by inserting a metal member between a plurality of electronic components when the plurality of electronic components are embedded in a cavity of a substrate, and a method of manufacturing the same.

In accordance with one aspect of the present invention to achieve the object, there is provided an electronic component embedded printed circuit board including: a substrate in which a cavity is formed; a plurality of electronic components embedded in the cavity; a metal member inserted between the plurality of electronic components; and insulating layers formed on both surfaces of the substrate to cover the plurality of electronic components.

Further, the electronic component embedded printed circuit board may further include a circuit pattern formed on a surface of the insulating layer; and a plurality of vias for electrically connecting the circuit pattern and the plurality of electronic components, respectively.

At this time, the plurality of vias may further electrically connect the circuit pattern and the metal member, respectively.

And an inner surface of the cavity may be applied with a metal for interconnection.

Moreover, the metal member may have the same width as the cavity.

Further, the plurality of electronic components may be embedded in parallel.

In addition, the substrate may be an insulating substrate.

Further, the electronic component embedded printed circuit board may further include an adhesive layer interposed between each electronic component and the metal member.

Moreover, the adhesive layer may be made of a metal-containing material.

Meanwhile, in accordance with another aspect of the present invention to achieve the object, there is provided a method of manufacturing an electronic component embedded printed circuit board including: forming a cavity in a substrate; embedding a first electronic component in the cavity; mounting a metal member on one surface of the first electronic component; embedding a second electronic component in one surface of the metal member; and forming insulating layers on both surfaces of the substrate to cover the plurality of electronic components.

The method may further include, before embedding the first electronic component in the cavity, attaching a fixing tape to a lower surface of the substrate to cover the cavity.

The method may further include, after embedding the first electronic component in the cavity, applying a first adhesive layer on one surface of the first electronic component.

The method may further include, after mounting the metal member on one surface of the first electronic component, applying a second adhesive layer on one surface of the metal member.

Forming the insulating layers on the both surfaces of the substrate to cover the plurality of electronic components may include: forming a first insulating layer on an upper surface of the substrate to cover the second electronic component; removing the fixing tape; and forming a second insulating layer on the lower surface of the substrate to cover the first electronic component.

The method may further include, after forming the insulating layers on the both surfaces of the substrate to cover the plurality of electronic components, forming a circuit pattern on the insulating layer.

The method may further include, after forming the insulating layers on the both surfaces of the substrate to cover the plurality of electronic components, forming a plurality of vias for electrically connecting the circuit pattern and the plurality of electronic components, respectively.

At this time, the plurality of vias may further electrically connect the circuit pattern and the metal member, respectively.

The method may further include, after forming the cavity in the substrate, applying an inner surface of the cavity with a metal for interconnection.

And the metal member may have the same width as the cavity.

The method may further include, after embedding the first electronic component in the cavity, disposing the first adhesive layer on one surface of the first electronic component and after mounting the metal member on one surface of the first electronic component, disposing the second adhesive layer on one surface of the metal member.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing an electronic component embedded printed circuit board in accordance with an embodiment of the present invention;

FIGS. 2 to 8 are cross-sectional views showing manufacturing processes of the electronic component embedded printed circuit board in accordance with an embodiment of the present invention;

FIG. 9 is a cross-sectional view showing an electronic component embedded printed circuit board in accordance with another embodiment of the present invention;

FIGS. 10 to 16 are cross-sectional views showing manufacturing processes of the electronic component embedded printed circuit board in accordance with another embodiment of the present invention;

FIG. 17 is a cross-sectional view showing an electronic component embedded printed circuit board in accordance with still another embodiment of the present invention; and

FIGS. 18 to 24 are cross-sectional views showing manufacturing processes of the electronic component embedded printed circuit board in accordance with still another embodiment of the present invention.

### DETAILED DESCRIPTION OF THE PREFERABLE EMBODIMENTS

Terms or words used in the present specification and claims should not be interpreted as being limited to typical or dictionary meanings, but should be interpreted as having meanings and concepts relevant to the technical spirit of the present invention based on the rule according to which an inventor can appropriately define the concept of the term to describe his/her own invention in the best manner.

Therefore, configurations shown in the embodiments and drawings of the present invention rather are examples of the most exemplary embodiment and do not represent all of the technical spirit of the invention. Thus, it will be understood that various equivalents and modifications that replace the configurations are possible when filing the present application.

Hereinafter, embodiments of the present invention will be described in detail with reference to the accompanying drawings.

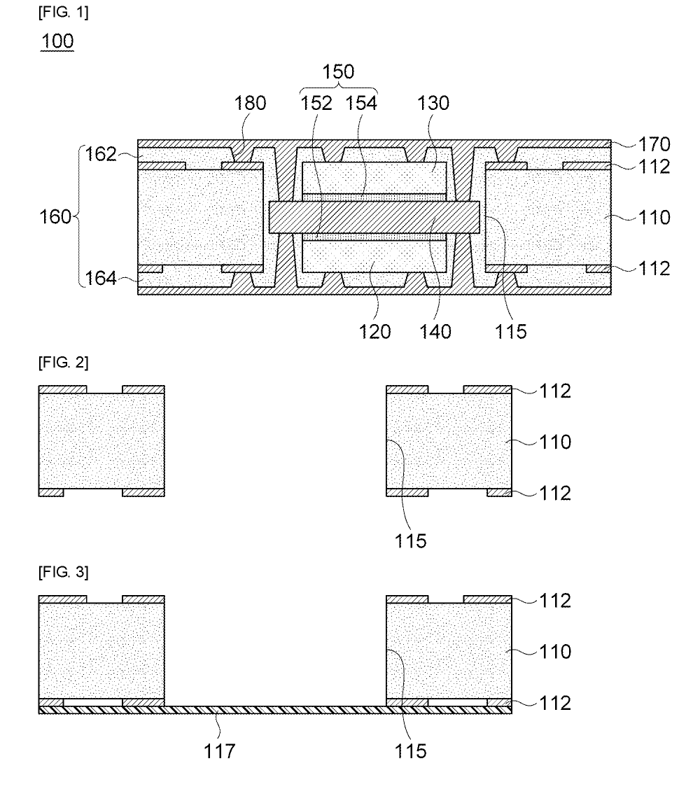

FIG. 1 is a cross-sectional view showing an electronic component embedded printed circuit board in accordance with an embodiment of the present invention.

As shown in FIG. 1, an electronic component embedded printed circuit board 100 includes a substrate 110, a cavity 115, a plurality of electronic components 120 and 130, a metal member 140, an adhesive layer 150, an insulating layer 160, a circuit pattern 170, and a plurality of vies 180.

The substrate 110 may be an insulating substrate, and a circuit pattern 112 may be formed on at least one of both surfaces of the insulating substrate.

The cavity 115 may be formed from one surface of the substrate 110 through the other surface of the substrate 110 and processed in correspondence to the position in which the plurality of electronic components 120 and 130 are embedded. More specifically, the cavity 115 may be formed in the substrate 110 by a method such as laser cutting, routing, or punching.

The plurality of electronic components 120 and 130, which are means embedded in the cavity 115 in parallel, may consist of a plurality of chips such as DRAM or NAND flash. In the present specification, for convenience of description, the first and second electronic components 120 and 130 are described as examples.

The metal member 140, which is a means inserted between the first and second electronic components 120 and 130, may be formed in a plate shape. The first electronic component 120 is embedded in the cavity 115, the metal member 140 is mounted on one surface of the first electronic component 120, and the second electronic component 130 is embedded in one surface of the metal member 140 so that the metal member 140 can be inserted between the first and second electronic components 120 and 130.

And since the metal member 140 has high thermal conductivity, it is possible to improve heat radiation characteristics by effectively radiating heat generated from the first and second electronic components 120 and 130.

The adhesive layer 150 includes a first adhesive layer 152 interposed between the first electronic component 120 and the metal member 140 and a second adhesive layer 154 interposed between the metal member 140 and the second electronic component 130, and the first adhesive layer 152 and the second adhesive layer 154 may be a die attach film DAF, a non-conductive adhesive NCA, or epoxy. In addition, it is possible to more improve the heat radiation characteristics by using the adhesive layer 150 made of a metal-containing material.

The insulating layer 160 may be formed on both surfaces of the substrate 110 to cover the first and second electronic components 120 and 130.

This insulating layer 160 includes a first insulating layer 162 formed on an upper surface of the substrate 110 to cover the second electronic component 130 and a second insulating layer 164 formed on a lower surface of the substrate 110 to cover the first electronic component 120. Accordingly, the first and second electronic components 120 and 130 can be buried by the insulating layer 160.

The circuit pattern 170 is formed on a surface of the insulating layer 160 and may be made of a conductive material such as copper.

The plurality of vias 180 electrically connect the circuit pattern 170 and the first and second electronic components 120 and 130, respectively. Accordingly, the first and second electronic components 120 and 130 can be electrically connected to the outside.

Further, the plurality of vias 180 may be configured to electrically connect the circuit pattern 170 and the metal member 140, respectively. Accordingly, it is possible to effectively radiate the heat generated from the first and second electronic components 120 and 130 to the outside.

And the plurality of vias 180 may be formed by forming via holes through a laser drilling or lithography method and plating a conductive material such as copper on one surface of the insulating layer 160 to fill the via holes.

FIGS. 2 to 8 are cross-sectional views showing manufacturing processes of an electronic component embedded printed circuit board in accordance with an embodiment of the present invention and describe manufacturing processes of the electronic component embedded printed circuit board shown in FIG. 1.

As shown in FIG. 2, a cavity 115 is formed in a substrate 110.

At this time, the substrate 110 may be an insulating substrate, and a circuit pattern 112 may be formed on at least one of both surfaces of the insulating substrate.

The cavity 115 may be formed from one surface of the substrate 110 through the other surface of the substrate 110 and processed in correspondence to the position in which a plurality of electronic components 120 and 130 are embedded. More specifically, the cavity 115 may be formed in the substrate 110 by a method such as laser cutting, routing, or punching.

Next, as shown in FIG. 3, a fixing tape 117 is attached to a lower surface of the substrate 110 to cover the cavity 115. At this time, the fixing tape 117, a heat-resistant tape which does not leave residue when removed, may be a tape made of a PI material.

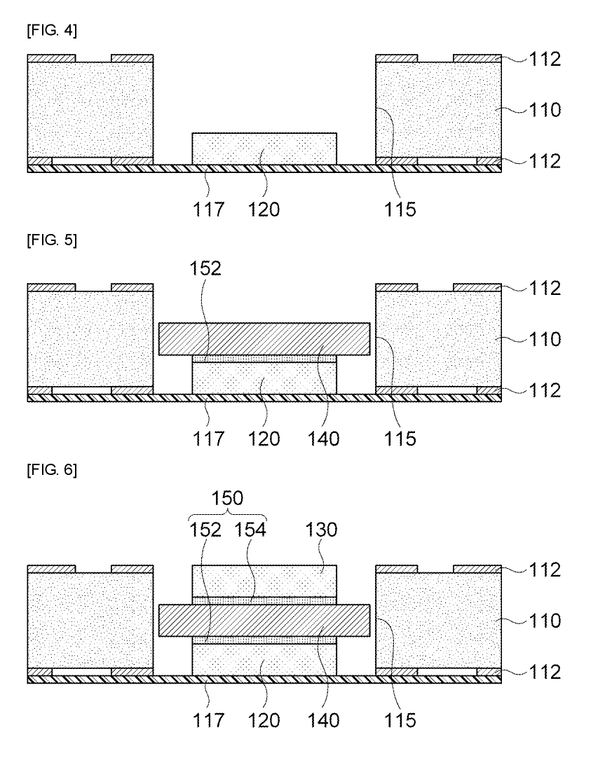

And as shown in FIG. 4, the first electronic component 120 is embedded in the cavity 115. The first electronic component 120 may consist of a plurality of chips such as RAM or NAND flash.

Next, as shown in FIG. 5, a first adhesive layer 152 is applied on one surface of the first electronic component 120, and a metal member 140 is mounted on one surface of the first electronic component 120 (that is, one surface of the first adhesive layer 152).

At this time, the metal member 140, which is a means inserted between the first and second electronic components 120 and 130, may be formed in a plate shape and can improve heat radiation characteristics by effectively radiating heat generated from the first and second electronic components 120 and 130 since it has high thermal conductivity.

In addition, it is possible to prevent warpage of the electronic component embedded printed circuit board 100 by controlling a thickness of the metal member 140 to uniformly maintain horizontal positions of the first and second electronic components 120 and 130 embedded in the cavity 115.

And the first adhesive layer 152, which is a means interposed between the first electronic component 120 and the metal member 140, may be a DAF, an NCA, or epoxy. In addition, it is possible to more improve the heat radiation characteristics by using a metal-containing material in the first adhesive layer 152.

Next, as shown in FIG. 6, a second adhesive layer 154 is applied on one surface of the metal member 140, and the second electronic component 130 is embedded in one surface of the second adhesive layer 154. Here, the second electronic component 130 may consist of a plurality of chips such as RAM or NAND flash.

And the second adhesive layer 154, which is also a means interposed between the second electronic component 130 and the metal member 140, may be a DAF, an NCA, or epoxy. Further, the second adhesive layer 154 may also be made of a metal-containing material to more improve the heat radiation characteristics.

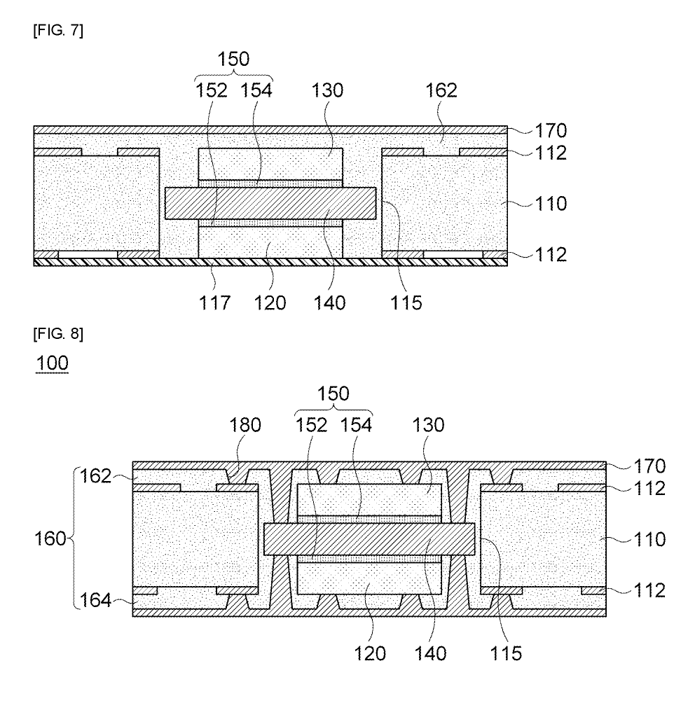

After that, as shown in FIG. 7, after a first insulating layer 162 is formed on an upper surface of the substrate 110 to cover the second electronic component 130, plating is performed to form a circuit pattern 170.

Next, as shown in FIG. 8, after the fixing tape 117 is removed, a second insulating layer 164 is formed on a lower surface of the substrate 110 to cover the first electronic component 120. Accordingly, the first and second electronic components 120 and 130 can be buried by the first and second insulating layers 162 and 164.

And the circuit pattern 170 is formed on a surface of an insulating layer 160 including the first and second insulating layers 162 and 164.

Further, a plurality of vias 180 are formed to electrically connect the circuit pattern 170 and the first and second electronic components 120 and 130, respectively. Accordingly, the first and second electronic components 120 and 130 can be electrically connected to the outside. Further, it is possible to effectively radiate heat generated from the first and second electronic components 120 and 130 to the outside by electrically connecting the circuit pattern 170 and the metal member 140 through the plurality of vias 180.

These plurality of vias 180 may be formed by forming via holes through a laser drilling or lithography method and plating a conductive material such as copper on one surface of the insulating layer 160 to fill the via holes.

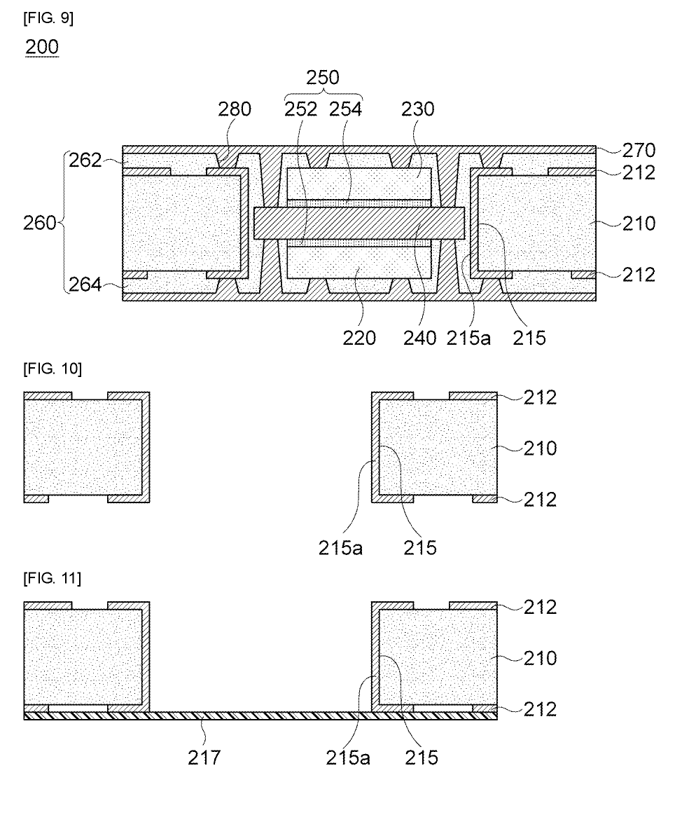

FIG. 9 is a cross-sectional view showing an electronic component embedded printed circuit board in accordance with another embodiment of the present invention.

As shown in FIG. 9, an electronic component embedded printed circuit board 200 includes a substrate 210, a cavity 215, a plurality of electronic components 220 and 230, a metal member 240, an adhesive layer 250, an insulating layer 260, a circuit pattern 270, and a plurality of vias 280.

The substrate 210 may be an insulating substrate, and a circuit pattern 212 may be formed on at least one of both surfaces of the insulating substrate. Further, interconnection, which is formed by applying a metal 215a on an inner surface of the cavity 215 for electrical connection between the both surfaces of the insulating substrate, may be formed inside the substrate 210.

The cavity 215 may be formed from one surface of the substrate 210 through the other surface of the substrate 210 and processed in correspondence to the position in which the plurality of electronic components 220 and 230 are embedded. More specifically, the cavity 215 may be formed in the substrate 210 by a method such as laser cutting, routing, or punching.

The plurality of electronic components 220 and 230, which are means embedded in the cavity 215 in parallel, may consist of a plurality of chips such as DRAM or NAND flash. In the present specification, for convenience of description, the first and second electronic components 220 and 230 are described as examples.

The metal member 240, which is a means inserted between the first and second electronic components 220 and 230, may be formed in a plate shape. The first electronic component 220 is embedded in the cavity 215, the metal member 240 is mounted on one surface of the first electronic component 220, and the second electronic component 230 is embedded in one surface of the metal member 240 so that the metal member 240 can be inserted between the first and second electronic components 220 and 230.

And since the metal member 240 has high thermal conductivity, it is possible to improve heat radiation characteristics by effectively radiating heat generated from the first and second electronic components 220 and 230.

Further, it is possible to effectively prevent warpage of the electronic component embedded printed circuit board 200 by controlling a thickness of the metal member 240 to uniformly maintain horizontal positions of the first and second electronic components 220 and 230 embedded in the cavity 215.

The adhesive layer 250 includes a first adhesive layer 252 interposed between the first electronic component 220 and the metal member 240 and a second adhesive layer 254 interposed between the metal member 240 and the second electronic component 230, and the first adhesive layer 252 and the second adhesive layer 254 may be a DAF, an NCA, or epoxy. In addition, it is possible to more improve the heat radiation characteristics by using the adhesive layer 250 made of a metal-containing material.

The insulating layer 260 may be formed on both surfaces of the substrate 210 to cover the first and second electronic components 220 and 230.

This insulating layer 260 includes a first insulating layer 262 formed on an upper surface of the substrate 210 to cover the second electronic component 230 and a second insulating layer 264 formed on a lower surface of the substrate 210 to cover the first electronic component 220. Accordingly, the first and second electronic components 220 and 230 can be buried by the insulating layer 260.

The circuit pattern 270 is formed on a surface of the insulating layer 260 and may be made of a conductive material such as copper.

The plurality of vias 280 electrically connect the circuit pattern 270 and the first and second electronic components 220 and 230, respectively. Accordingly, the first and second electronic components 220 and 230 can be electrically connected to the outside.

Further, the plurality of vias 280 may be configured to electrically connect the circuit pattern 270 and the metal member 240, respectively. Accordingly, it is possible to effectively radiate the heat generated from the first and second electronic components 220 and 230 to the outside.

And the plurality of vias 280 may be formed by forming via holes through a laser drilling or lithography method and plating a conductive material such as copper on one surface of the insulating layer 260 to fill the via holes.

FIGS. 10 to 16 are cross-sectional views showing manufacturing processes of an electronic component embedded printed circuit board in accordance with another embodiment of the present invention and describe manufacturing processes of the electronic component embedded printed circuit board shown in FIG. 9.

As shown in FIG. 10, a cavity 215 is formed in a substrate 210.

At this time, the substrate 210 may be an insulating substrate, and a circuit pattern 212 may be formed on at least one of both surfaces of the insulating substrate. Further, interconnection, which is formed by applying a metal 215a on an inner surface of the cavity 215 for electrical connection between the both surfaces of the insulating substrate, may be formed inside the substrate 210.

And the cavity 215 may be formed from one surface of the substrate 210 through the other surface of the substrate 210 and processed in correspondence to the position in which a plurality of electronic components 220 and 230 are embedded. More specifically, the cavity 215 may be formed in the substrate 210 by a method such as laser cutting, routing, or punching.

As shown in FIG. 11, a fixing tape 217 is attached to a lower surface of the substrate 210 to cover the cavity 215. Here, the fixing tape 217, a heat-resistant tape which does not leave residue when removed, may be a tape made of a PI material.

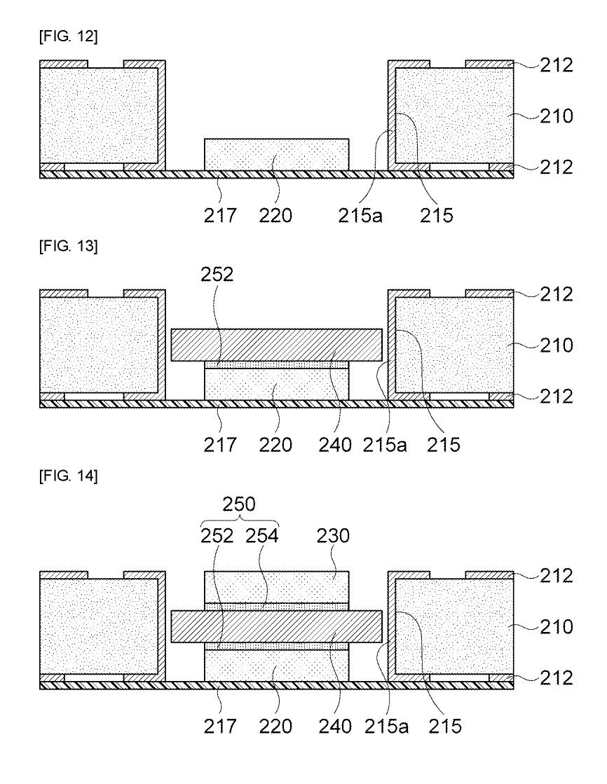

Next, as shown in FIG. 12, the first electronic component 220 is embedded in the cavity 115. The first electronic component 220 may consist of a plurality of chips such as RAM or NAND flash.

And as shown in FIG. 13, a first adhesive layer 252 is applied on one surface of the first electronic component 220, and a metal member 240 is mounted on one surface of the first electronic component 220 (that is, one surface of the first adhesive layer 252).

At this time, the metal member 240, which is a means inserted between the first and second electronic components 220 and 230, may be formed in a plate shape and can improve heat radiation characteristics by effectively radiating heat generated from the first and second electronic components 220 and 230 since it has high thermal conductivity.

Further, the first adhesive layer 252, which is a means interposed between the first electronic component 220 and the metal member 240, may be a DAF, an NCA, or epoxy. In addition, it is possible to more improve the heat radiation characteristics by using a metal-containing material in the first adhesive layer 252.

Next, as shown in FIG. 14, a second adhesive layer 254 is applied on one surface of the metal member 240, and the second electronic component 230 is embedded in one surface of the second adhesive layer 254. Here, the second electronic component 230 may consist of a plurality of chips such as RAM or NAND flash.

And the second adhesive layer 254, which is a means interposed between the second electronic component 230 and the metal member 240, may be a DAF, an NCA, or epoxy. In addition, it is possible to more improve the heat radiation characteristics by using a metal-containing material in the second adhesive layer 254.

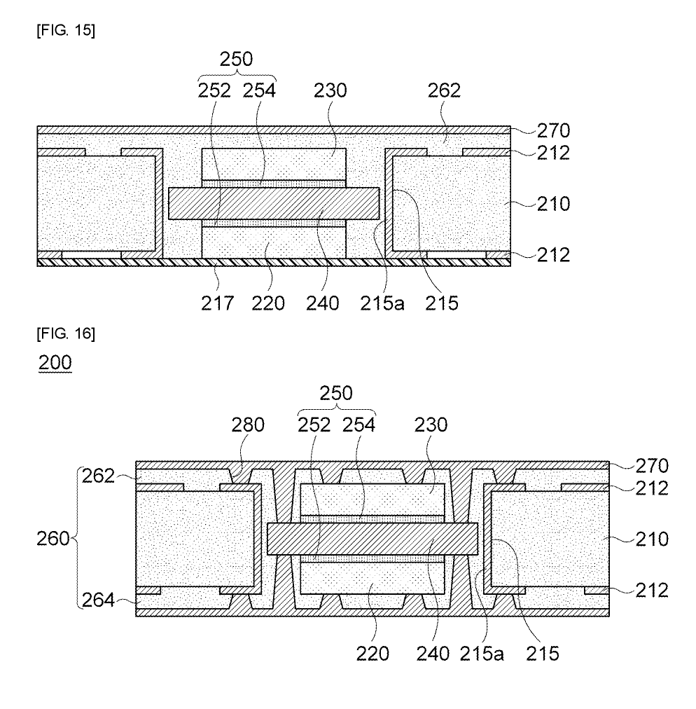

After that, as shown in FIG. 15, after a first insulating layer 262 is formed on an upper surface of the substrate 210 to cover the second electronic component 230, plating is performed to form a circuit pattern 270.

Next, as shown in FIG. 16, after the fixing tape 217 is removed, a second insulating layer 264 is formed on the lower surface of the substrate 210 to cover the first electronic component 220. Accordingly, the first and second electronic components 220 and 230 can be buried by the first and second insulating layers 262 and 264.

And the circuit pattern 270 is formed on a surface of an insulating layer 260 including the first and second insulating layers 262 and 264.

Further, a plurality of vias 280 are formed to electrically connect the circuit pattern 270 and the first and second electronic components 220 and 230, respectively. Accordingly, the first and second electronic components 220 and 230 can be electrically connected to the outside. Further, it is possible to effectively radiate the heat generated from the first and second electronic components 220 and 230 to the outside by electrically connecting the circuit pattern 270 and the metal member 240 through the plurality of vias 280.

These plurality of vias 280 may be formed by forming via holes through a laser drilling or lithography method and plating a conductive material such as copper on one surface of the insulating layer 260 to fill the via holes.

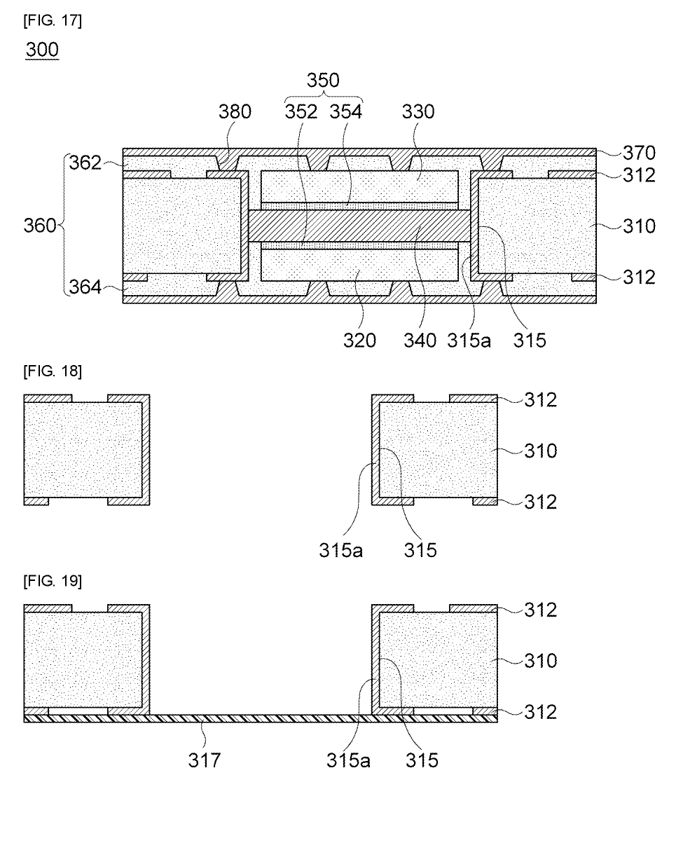

FIG. 17 is a cross-sectional view showing an electronic component embedded printed circuit board in accordance with still another embodiment of the present invention.

As shown in FIG. 17, an electronic component embedded printed circuit board 300 includes a substrate 310, a cavity 315, a plurality of electronic components 320 and 330, a metal member 340, an adhesive layer 350, an insulating layer 360, a circuit pattern 370, and a plurality of vias 380.

The substrate 310 may be an insulating substrate, and a circuit pattern 312 may be formed on at least one of both surfaces of the insulating substrate. Further, interconnection, which is formed by applying a metal 315a on an inner surface of the cavity 315 for electrical connection between the both surfaces of the insulating substrate, may be formed inside the substrate 310.

The cavity 315 may be formed from one surface of the substrate 310 through the other surface of the substrate 310 and processed in correspondence to the position in which the plurality of electronic components 320 and 330 are embedded. More specifically, the cavity 315 may be formed in the substrate 310 by a method such as laser cutting, routing, or punching.

The plurality of electronic components 320 and 330, which are means embedded in the cavity 315 in parallel, may consist of a plurality of chips such as DRAM or NAND flash. In the present specification, for convenience of description, the first and second electronic components 320 and 330 are described as examples.

The metal member 340, which is a means inserted between the first and second electronic components 320 and 330, may be formed in a plate shape. The first electronic component 320 is embedded in the cavity 315, the metal member 340 is mounted on one surface of the first electronic component 320, and the second electronic component 330 is embedded in one surface of the metal member 340 so that the metal member 340 can be inserted between the first and second electronic components 320 and 330.

And since the metal member 340 has high thermal conductivity, it is possible to improve heat radiation characteristics by effectively radiating heat generated from the first and second electronic components 320 and 330.

In addition, it is possible to easily radiate the heat transmitted to the metal member 340 to the outside by processing the cavity 315 and the metal member 340 with the same or similar width to bring the metal member 340 into contact with the metal 315a on the inner surface of the cavity 315.

Further, it is possible to prevent warpage of the electronic component embedded printed circuit board 300 by controlling a thickness of the metal member 340 to uniformly maintain horizontal positions of the first and second electronic components 320 and 330 embedded in the cavity 315.

The adhesive layer 350 includes a first adhesive layer 352 interposed between the first electronic component 320 and the metal member 340 and a second adhesive layer 354 interposed between the metal member 340 and the second electronic component 330, and the first adhesive layer 352 and the second adhesive layer 354 may be a DAF, an NCA, or epoxy. In addition, it is possible to more improve the heat radiation characteristics by using the adhesive layer 350 made of a metal-containing material.

The insulating layer 360 may be formed on both surfaces of the substrate 310 to cover the first and second electronic components 320 and 330.

This insulating layer 360 includes a first insulating layer 362 formed on an upper surface of the substrate 310 to cover the second electronic component 330 and a second insulating layer 364 formed on a lower surface of the substrate 310 to cover the first electronic component 320. Accordingly, the first and second electronic components 320 and 330 can be buried by the insulating layer 360.

The circuit pattern 370 is formed on a surface of the insulating layer 360 and may be made of a conductive material such as copper.

The plurality of vias 380 electrically connect the circuit pattern 370 and the first and second electronic components 320 and 330, respectively. Accordingly, the first and second electronic components 320 and 330 can be electrically connected to the outside.

And the plurality of vias 380 may be formed by forming via holes through a laser drilling or lithography method and plating a conductive material such as copper on one surface of the insulating layer 360 to fill the via holes.

FIGS. 18 to 24 are cross-sectional views showing manufacturing processes of an electronic component embedded printed circuit board in accordance with still another embodiment of the present invention and describe manufacturing processes of the electronic component embedded printed circuit board shown in FIG. 17.

As shown in FIG. 18, a cavity 315 is formed in a substrate 310.

At this time, the substrate 310 may be an insulating substrate, and a circuit pattern 312 may be formed on at least one of both surfaces of the insulating substrate. Further, interconnection, which is formed by applying a metal 315a on an inner surface of the cavity 315 for electrical connection between the both surfaces of the insulating substrate, may be formed inside the substrate 310.

And the cavity 315 may be formed from one surface of the substrate 310 through the other surface of the substrate 310 and processed in correspondence to the position in which a plurality of electronic components 320 and 330 are embedded. More specifically, the cavity 315 may be formed in the substrate 310 by a method such as laser cutting, routing, or punching.

As shown in FIG. 19, a fixing tape 317 is attached to a lower surface of the substrate 310 to cover the cavity 315. Here, the fixing tape 317, a heat-resistant tape which does not leave residue when removed, may be a tape made of a PI material.

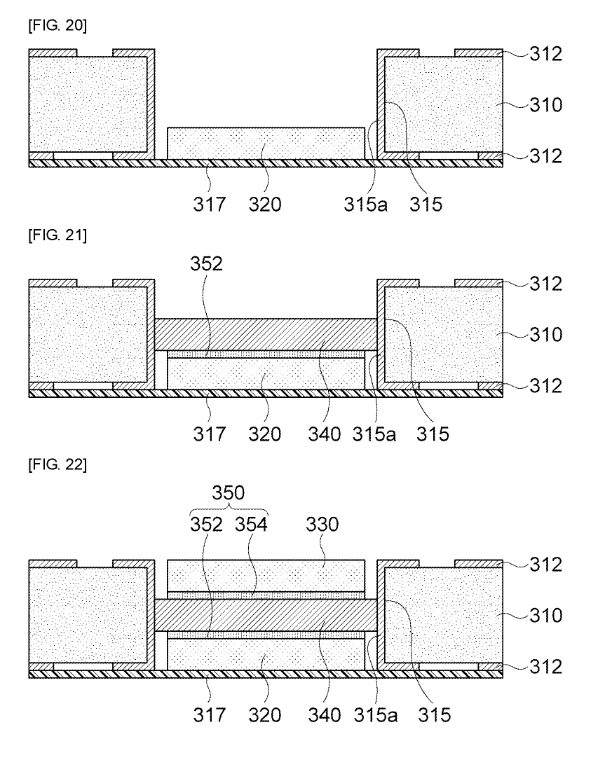

Next, as shown in FIG. 20, the first electronic component 320 is embedded in the cavity 315. The first electronic component 320 may consist of a plurality of chips such as RAM or NAND flash.

And as shown in FIG. 21, a first adhesive layer 352 is applied on one surface of the first electronic component 320, and a metal member 340 is mounted on one surface of the first electronic component 320 (that is, one surface of the first adhesive layer 352).

At this time, the metal member 340, which is a means inserted between the first and second electronic components 320 and 330, may be formed in a plate shape and can improve heat radiation characteristics by effectively radiating heat generated from the first and second electronic components 320 and 330 since it has high thermal conductivity.

Further, it is possible to easily radiate the heat transmitted to the metal member 340 to the outside by processing the cavity 315 and the metal member 340 with the same or similar width to bring the metal member 340 into contact with the metal 315a on the inner surface of the cavity 315.

And it is possible to prevent warpage of the electronic component embedded printed circuit board 300 by controlling a thickness of the metal member 340 to uniformly maintain horizontal positions of the first and second electronic components 320 and 330 embedded in the cavity 315.

Further, the first adhesive layer 352, which is a means interposed between the first electronic component 320 and the metal member 340, may be a DAF, an NCA, or epoxy. In addition, it is possible to more improve the heat radiation characteristics by using a metal-containing material in the first adhesive layer 352.

Next, as shown in FIG. 22, a second adhesive layer 354 is applied on one surface of the metal member 340, and the second electronic component 330 is embedded in one surface of the second adhesive layer 354. Here, the second electronic component 330 may consist of a plurality of chips such as RAM or NAND flash.

And the second adhesive layer 354, which is a means interposed between the second electronic component 330 and the metal member 340, may be a DAF, an NCA, or epoxy. In addition, it is possible to more improve the heat radiation characteristics by using a metal-containing material in the second adhesive layer 354.

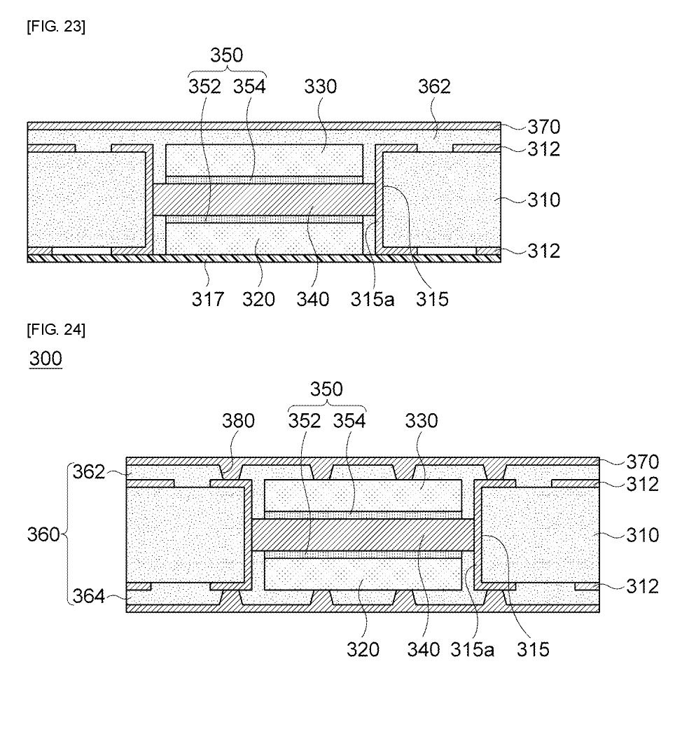

After that, as shown in FIG. 23, after a first insulating layer 362 is formed on an upper surface of the substrate 310 to cover the second electronic component 330, plating is performed to form a circuit pattern 370.

Next, as shown in FIG. 24, after the fixing tape 317 is removed, a second insulating layer 364 is formed on the lower surface of the substrate 310 to cover the first electronic component 320. Accordingly, the first and second electronic components 320 and 330 can be buried by the first and second insulating layers 362 and 364.

And the circuit pattern 370 is formed on a surface of an insulating layer 360 including the first and second insulating layers 362 and 364.

Further, a plurality of vias 380 are formed to electrically connect the circuit pattern 370 and the first and second electronic components 320 and 330, respectively. Accordingly, the first and second electronic components 320 and 330 can be electrically connected to the outside. Further, it is possible to effectively radiate the heat generated from the first and second electronic components 320 and 330 to the outside by electrically connecting the circuit pattern 370 and the metal member 340 through the plurality of vias 380.

These plurality of vias 380 may be formed by forming via holes through a laser drilling or lithography method and plating a conductive material such as copper on one surface of the insulating layer 360 to fill the via holes.

As described above, according to an electronic component embedded printed circuit board and a method of manufacturing the same in accordance with an embodiment of the present invention, when a plurality of electronic components are mounted in a cavity of a substrate, it is possible to effectively improve heat radiation characteristics by inserting a metal member between the plurality of electronic components.

Accordingly, it is possible to satisfy a need for high integration of components by increasing the number of electronic components embedded in the cavity.

And it is possible to easily radiate heat transmitted to the metal member by processing the cavity and the metal member with the same width to bring the metal member into contact with a metal on an inner surface of the cavity.

Further, it is possible to prevent warpage of the electronic component embedded printed circuit board by adjusting a thickness of the metal member to uniformly maintain horizontal positions of the electronic components embedded in the cavity.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. An electronic component embedded printed circuit board comprising:
a substrate in which a cavity is formed;
a plurality of electronic components embedded in the cavity;
a metal member inserted between the plurality of electronic components; and
insulating layers formed on both surfaces of the substrate to cover the plurality of electronic components.

2. The electronic component embedded printed circuit board according to claim 1, further comprising:
a circuit pattern formed on a surface of the insulating layer; and
a plurality of vias for electrically connecting the circuit pattern and the plurality of electronic components, respectively.

3. The electronic component embedded printed circuit board according to claim 2, wherein the plurality of vias further electrically connect the circuit pattern and the metal member, respectively.

4. The electronic component embedded printed circuit board according to claim 3, wherein an inner surface of the cavity is applied with a metal for interconnection.

5. The electronic component embedded printed circuit board according to claim 4, wherein the metal member has the same width as the cavity.

6. The electronic component embedded printed circuit board according to claim 1, wherein the plurality of electronic components are embedded in parallel.

7. The electronic component embedded printed circuit board according to claim 1, wherein the substrate is an insulating substrate.

8. The electronic component embedded printed circuit board according to claim 1, further comprising:
an adhesive layer interposed between each electronic component and the metal member.

9. The electronic component embedded printed circuit board according to claim 8, wherein the adhesive layer is made of a metal-containing material.

10. A method of manufacturing an electronic component embedded printed circuit board comprising:
forming a cavity in a substrate;
embedding a first electronic component in the cavity;
mounting a metal member on one surface of the first electronic component;
embedding a second electronic component in one surface of the metal member; and
forming insulating layers on both surfaces of the substrate to cover the plurality of electronic components.

11. The method of manufacturing an electronic component embedded printed circuit board according to claim 10, further comprising, before embedding the first electronic component in the cavity, attaching a fixing tape to a lower surface of the substrate to cover the cavity.

12. The method of manufacturing an electronic component embedded printed circuit board according to claim 10, further comprising, after embedding the first electronic component in the cavity, applying a first adhesive layer on one surface of the first electronic component.

13. The method of manufacturing an electronic component embedded printed circuit board according to claim 12, further comprising, after mounting the metal member on one surface of the first electronic component, applying a second adhesive layer on one surface of the metal member.

14. The method of manufacturing an electronic component embedded printed circuit board according to claim 11, wherein forming the insulating layers on the both surfaces of the substrate to cover the plurality of electronic components comprises:
forming a first insulating layer on an upper surface of the substrate to cover the second electronic component;
removing the fixing tape; and
forming a second insulating layer on the lower surface of the substrate to cover the first electronic component.

15. The method of manufacturing an electronic component embedded printed circuit board according to claim 10, further comprising, after forming the insulating layers on the both surfaces of the substrate to cover the plurality of electronic components, forming a circuit pattern on the insulating layer.

16. The method of manufacturing an electronic component embedded printed circuit board according to claim 15, further comprising, after forming the insulating layers on the both surfaces of the substrate to cover the plurality of electronic components, forming a plurality of vias for electrically connecting the circuit pattern and the plurality of electronic components, respectively.

17. The method of manufacturing an electronic component embedded printed circuit board according to claim 16, wherein the plurality of vias further electrically connect the circuit pattern and the metal member, respectively.

18. The method of manufacturing an electronic component embedded printed circuit board according to claim 10, further comprising, after forming the cavity in the substrate, applying an inner surface of the cavity with a metal for interconnection.

19. The method of manufacturing an electronic component embedded printed circuit board according to claim 10, wherein the metal member has the same width as the cavity.

20. The method of manufacturing an electronic component embedded printed circuit board according to claim 10, further comprising, after embedding the first electronic component in the cavity, disposing the first adhesive layer on one surface of the first electronic component, and after mounting the metal member on one surface of the first electronic component, disposing the second adhesive layer on one surface of the metal member.
